(19) United States
(12) Patent Application Publication
(10) Pub. No.: US 2026/0047453 A1
(43) Pub. Date: Feb. 12, 2026

(54) SEMICONDUCTOR PACKAGE STRUCTURE AND MANUFACTURING METHOD THEREOF

(71) Applicant: Samsung Electronics Co., Ltd., Suwon-si (KR)

(72) Inventor: Peng ZHANG, Suzhou (CN)

(73) Assignee: Samsung Electronics Co., Ltd., Suwon-si (KR)

(21) Appl. No.: 18/884,566

(22) Filed: Sep. 13, 2024

(30) Foreign Application Priority Data
Aug. 6, 2024 (CN) 202411074161.5

(51) Int. Cl. H01L 23/00; H01L 23/31; H01L 23/538; H01L 25/00; H01L 25/065

(52) U.S. Cl. CPC H01L 24/48; H01L 23/5385; H01L 24/24; H01L 24/73; H01L 24/82; H01L 24/85; H01L 24/92; H01L 25/0657; H01L 25/50; H01L 23/3107; H01L 2224/24155; H01L 2224/244; H01L 2224/48245; H01L 2224/73227; H01L 2224/8236; H01L 2224/85947; H01L 2224/9202; H01L 2224/92164; H01L 2225/0651; H01L 2225/06562

(57) ABSTRACT

A semiconductor package includes: a substrate; a chip stack on the substrate; a first interface, in a first region of the substrate and having a first circuit layer; a second interface, in a second region of the substrate and having a second circuit layer, and the chip stack between the first and second interface; a first bonding wire, connected to a first chip and having a first contact point; a second bonding wire, connected to a second chip and having a second contact point; an encapsulation layer, surrounding the chip stack, the first and second interface, the first and second bonding wire on the substrate, and exposing the first and second contact point, and the first and second circuit layer; and a redistribution layer, on the encapsulation layer and connecting the first contact point and the second contact point to the first circuit layer and the second circuit layer.

### CROSS-REFERENCE TO RELATED APPLICATION

This application claims priority to and benefit under 35 U.S. C. § 119 to Chinese Patent Application No. 202411074161.5, filed on Aug. 6, 2024 in the China National Intellectual Property Administration (CNIPA), the disclosure of which is herein incorporated by reference in its entirety.

### BACKGROUND

Example embodiments of the inventive concepts relate to the semiconductor package field, and specifically, relate to semiconductor package structures based on a wire bonding technology and a manufacturing method thereof.

A vertical wire bonding (vertical wire bonding, also referred to as vertical wire bonding or vertical welding wire bonding) process is prone to wire sweeping (wire sweeping, that is, the sagging or bending of the wire causes mutual contact to occur a short circuit), which results in the redistribution layer (RDL) of a fan-out package being affected by precision upon wiring, a yield of the package is relatively poor, and a pitch is difficult to reduce.

The above information is only used for enhancing the understanding for the background of the present inventive concepts.

### SUMMARY

Example embodiments of the inventive concepts disclose a semiconductor package structure based on a wire bonding technology and a manufacturing method thereof to improve the process yield.

An aspect of the inventive concepts provide a semiconductor package structure, and the semiconductor package structure includes: a support substrate; a chip stack body, including a plurality of chips stacked on the support substrate; a first interface, in a first edge region of the support substrate, and a first circuit layer on an upper surface of the first interface; a second interface, in a second edge region opposite to the first edge region of the support substrate, a second circuit layer on an upper surface of the second interface, and the chip stack body between the first interface and the second interface; a first bonding wire, connected to a first chip of the plurality of chips and having a first contact point at an end thereof; a second bonding wire, connected to a second chip of the plurality of chips and having a second contact point at an end thereof; an encapsulation layer, surrounding the chip stack body, the first interface, the second interface, the first bonding wire and the second bonding wire on the support substrate, and exposing the first contact point, the second contact point, the first circuit layer and the second circuit layer; and a redistribution layer, on the encapsulation layer and electrically connecting the first contact point and the second contact point to the first circuit layer and the second circuit layer, respectively.

An aspect of the inventive concepts provide a semiconductor package structure, and the semiconductor package structure includes: a support substrate; a chip stack body, including a plurality of chips stacked on the support substrate; a first interface, in a first edge region of the support substrate, and a first circuit layer on an upper surface of the first interface; a second interface, in a second edge region opposite to the first edge region of the support substrate, a second circuit layer on an upper surface of the second interface, and the chip stack body between the first interface and the second interface; a first bonding wire, connected to a first chip of the plurality of chips and having a first contact point at an end thereof; a second bonding wire, connected to a second chip of the plurality of chips and having a second contact point at an end thereof, and the first chip is between the support substrate and the second chip, and each of the first chip and the second chip are vertically offset in a horizontal direction; an encapsulation layer, surrounding the chip stack body, the first interface, the second interface, the first bonding wire and the second bonding wire on the support substrate, and exposing the first contact point, the second contact point, the first circuit layer and the second circuit layer; and a redistribution layer, on the encapsulation layer and electrically connecting the first contact point and the second contact point to the first circuit layer and the second circuit layer, respectively.

Aspects of the inventive concepts provides a method of manufacturing the semiconductor package structure, and the method includes: disposing a first interface and a second interface in a first edge region of a support substrate and a second edge region opposite to the first edge region, respectively, wherein a first circuit layer is formed on an upper surface of the first interface, and a second circuit layer is formed on an upper surface of the second interface; disposing a first chip on the support substrate, the first chip being located between the first interface and the second interface; electrically connecting the first chip to the first circuit layer using a first bonding wire, a portion of the first bonding wire that extends higher than the first circuit layer forming a first wire loop; disposing a second chip on the first chip to form a chip stack body; electrically connecting the second chip to the second circuit layer using a second bonding wire, a portion of the second bonding wire that extends higher than the second circuit layer forming a second wire loop; packaging the chip stack body, the first interface, the second interface, the first bonding wire and the second bonding wire on the support substrate using an encapsulation layer; removing an upper portion of the encapsulation layer to expose the first circuit layer and the second circuit layer, and removing the first wire loop and the second wire loop simultaneously to form a first contact point and a second contact point exposed to the encapsulation layer, respectively; and disposing a redistribution layer on the encapsulation layer to electrically connect the first contact point and the second contact point to the first circuit layer and the second circuit layer, respectively.

### BRIEF DESCRIPTION OF THE DRAWINGS

The above and other features and advantages of the inventive concepts will become clear from the following detailed descriptions for example embodiments, taken in conjunction with drawings. In the drawings, the same drawing marks will always indicate same components.

FIG. 1 illustrates a semiconductor package structure according to a comparative example.

FIG. 2 illustrates a semiconductor package structure according to some example embodiments of the inventive concepts.

FIG. 3 illustrates a semiconductor package structure according to some embodiments of the inventive concepts.

FIG. 4 illustrates a semiconductor package structure shown in FIG. 3 according to a comparative example.

FIG. 5 illustrates the semiconductor package structure according to the embodiment shown in FIG. 3.

FIG. 6 illustrates a process flowchart of manufacturing methods of the semiconductor package structures according to some example embodiments of the inventive concepts.

FIGS. 7-12 illustrate steps of the manufacturing methods of the semiconductor package structures according to some example embodiments of the inventive concepts.

### DETAILED DESCRIPTION

Various example embodiments of the present inventive concepts will be sufficiently described below by referring to drawings of some shown example embodiments. However, the present inventive concepts can be implemented in many different forms, and should not be interpreted to be limited to the example embodiments elaborated hereto. On the contrary, the description will be thorough and complete by providing these example embodiments, and the example embodiments will convey the scope of the inventive concept to those skilled in the art. In the drawings, to be clear, sizes of a layer and an area may be exaggerated.

For easy description, spatial relevancy terms (such as “below”, “beneath”, “under”, “above”, “on”, etc.) are used herein to describe a relationship between one element and the other elements as illustrated in the drawings. It should be understood that, the spatial relevancy terms also intend to include different orientations of a device in a usage or an operation, other than the orientations as described in the drawings. For example, if the device in the drawings is flipped, the element described to be “beneath” or “below” the other element shall be modified as “above” the other element. Therefore, the term “below” may include the “upper” and “lower” orientations. The device can be directed towards another orientation (rotated by 90 degree or located in another orientation), and the spatial relevancy terms used herein should be interpreted accordingly.

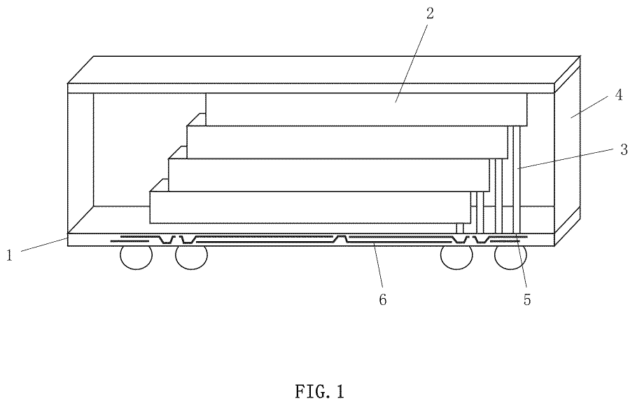

FIG. 1 illustrates a semiconductor package structure according to a comparative example. Referring to FIG. 1, a manufacturing method of the semiconductor package structure may include the following steps: firstly, stacking a plurality of chips 2 on the upper surface of the substrate 1 along a vertical direction; secondly, electrically connecting the plurality of chips 2 through a plurality of wires 3 using a vertical wire bonding technology, and each of the plurality of wires 3 having a vertical loop; next, after packaging the obtained structure using a resin 4 such as EMC, removing extra loops of the plurality of wires 3 located at a surface of the lowermost chip 2, to form exposed interconnect metal contact points 5 at a same level; and finally, connecting the exposed interconnect metal contact points 5 using RDL 6, and forming a solder ball 7 that can be used for external interconnection on a lower surface of the RDL 6.

The semiconductor package structure described above may have the following problems: first, since a difficulty of a vertical wire bonding process is relatively large, it is easy to cause wire deformation, and the wire sweeping in the packaging process is serious, which may affect the rewiring precision of the package; second, because the vertical loop does not easily form a large fan-out area, an arrangement of lower chips needs to be adjusted to realize a larger area.

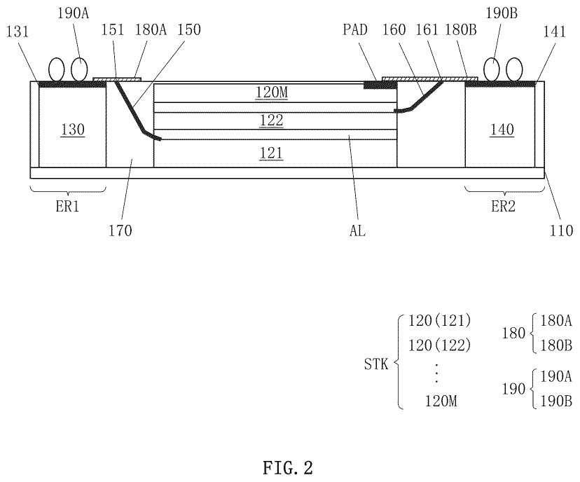

FIG. 2 illustrates a semiconductor package structure according to some example embodiments of the inventive concepts. As illustrated in FIG. 2, a semiconductor package structure 100 includes: a support substrate 110; a chip stack body STK, including a plurality of chips 120 stacked on the support substrate 110; a first interface 130, disposed in a first edge region ER1 of the support substrate 110, and a first circuit layer 131 being formed on an upper surface of the first interface 130; a second interface 140, disposed in a second edge region ER2 of the support substrate 110 opposite to the first edge region ER1, a second circuit layer 141 being formed on an upper surface of the second interface 140, and the chip stack body STK being located between the first interface 130 and the second interface 140; a first bonding wire 150, connected to a first chip 121 of the plurality of chips 120, and having a first contact point 151 at an end of the first bonding wire 150; a second bonding wire 160, connected to a second chip 122 of the plurality of chips 120, and having a second contact point 161 at an end of the second bonding wire 160; an encapsulation layer 170, packaging (e.g., surrounding) the chip stack body STK, the first interface 130, the second interface 140, the first bonding wire 150 and the second bonding wire 160 on the support substrate 110, and exposing the first contact point 151, the second contact point 161, the first circuit layer 131 and the second circuit layer 141; and a redistribution layer 180, disposed on the encapsulation layer 170 and electrically connecting the first contact point 151 and the second contact point 161 to the first circuit layer 131 and the second circuit layer 141, respectively.

The semiconductor package structure according to the example embodiments of the inventive concepts may improve the wire sweeping problem caused when realizing a fan-out package structure based on the wire bonding technology. For example, by disposing the first interface 130 and the second interface 140 with an interconnect layer formed by the first circuit layer 131, the second circuit layer 140 and the redistribution layer 180, the precision of wiring may be improved and a shortened interconnect path may be achieved. In some example embodiments, the bonding wires 150 and 160 may include metal materials such as copper (Cu), aluminum (Al) or the like.

In some example embodiments, the support substrate 110 may include, for example, a multilayer printed circuit board. The plurality of chips 120 may include, for example, a memory chip or a controller chip. Each of the first interface 130 and the second interface 140 may include an insulating material. The first interface 130 and the second interface 140 may be formed in a column shape with a certain height. For example, the first interface 130 and the second interface 140 may have a similar height (e.g., a top surface of the first interface 130 may be the same distance from a top surface of the support substrate 110 as a top surface of the second interface 140). The first circuit layer 131 and the second circuit layer 141 may be respectively formed on upper surfaces of the first interface 130 and the second interface 140 and include a plurality of layers of wirings and via holes.

In some example embodiments, the semiconductor package structure 100 may further include an external terminal 190. The external terminal 190 is disposed on the first circuit layer 131 and the second circuit layer 141 and spaced apart from the redistribution layer 180 along the horizontal direction. The external terminal 190 may be formed as a solder ball. An external signal may be transmitted to the first circuit layer 131 and the second circuit layer 141 of the semiconductor package structure 100 via the external terminal 190, and further transmitted to the first chip 121 and the second chip 122 via the redistribution layer 180 electrically connected with the first circuit layer 131 and the second circuit layer 141.

In some example embodiments, each of the plurality of chips 120 may include an active surface and an inactive surface opposite to the active surface. The active surface of each chip 120 may face the redistribution layer 180, and the inactive surface thereof may face the support substrate 110. An input/output pad may be disposed on the active surface of each chip 120.

In some example embodiments, the plurality of chips 120 may include the first chip 121 and the second chip 122 sequentially stacked on the support substrate 110. The first pad located on the active surface of the first chip 121 may be disposed between the first interface 130 and the chip stack body STK, and connected to the first bonding wire 150. The second pad located on the active surface of the second chip 122 may be disposed between the second interface 140 and the chip stack body STK, and connected to the second bonding wire 160. For example, the first pad and the second pad may be respectively located at both sides of the chip stack body STK. The first pad may be located at a level lower than that of the second pad, such that a length of the first bonding wire 150 may be larger than that of the second bonding wire 160. However, the example embodiments are not so limited thereto, for example, the first pad may be located at a level higher than that of the second pad, such that a length of the first bonding wire 150 may be shorter than that of the second bonding wire 160.

In some example embodiments, the plurality of chips 120 may include a plurality of first chips 121 and a plurality of second chips 122. The plurality of first chips 121 and the plurality of second chips 122 may be alternately stacked on the support substrate 110 and aligned along the horizontal direction. For example, the lowermost first chip of the plurality of first chips 121 may be disposed on the support substrate 110 and in contact with an upper surface of the support substrate 110. The lowermost second chip of the plurality of second chips 122 may be disposed on the lowermost first chip and an adhesive layer AL may be located between them. For example, the adhesive layer AL may be a die adhesive film (DAF). In this case, the first pad of the lowermost first chip may be covered by the adhesive layer AL, and a portion of the first bonding wire 150 that is in contact with the first pad may be buried in the adhesive layer AL. That is to say, the bonding wire 150 may extend between adjacent first chips 121 a second chips 122 in the adhesive layer AL.

In some example embodiment, the plurality of chips 120 may further include an uppermost chip 120M. A size and function of the uppermost chip 120M may be different from those of the first chip and the second chip. The uppermost chip 120M may be connected to the redistribution layer 180 via the pad PAD disposed on the active surface thereof.

In some example embodiments, the encapsulation layer 170 may cover the active surface of the uppermost chip 120M and expose the pad PAD of the uppermost chip 120M. Thus, the uppermost chip 120M disposed adjacent to the second interface 140 may be electrically connected to the second circuit layer 141, the second bonding wire 160 and the second chip 122 via the pad PAD and the redistribution layer 180. However, the example embodiments of the inventive concepts are not so limited thereto. Although not illustrated, the pad of the uppermost chip 120M may be disposed adjacent to the first interface 130, and may be electrically connected to the first circuit layer 131, the first bonding wire 150 and the first chip 121 via the redistribution layer 180.

In some example embodiments, since a planarization process such as chemical-mechanical polishing (CMP) is performed on the encapsulation layer 170, the upper surface of the pad PAD of the uppermost chip 120M, the upper surface of the first circuit layer 131, the upper surface of the second circuit layer 141 and the upper surface of the encapsulation layer 170 may be located at the same level.

In some example embodiments, the redistribution layer 180 may include a first portion 180A disposed on the first interface 130 and a second portion 180B disposed on the second interface 140. The first portion 180A may electrically connect the first contact point 151 to the first circuit layer 131. The second portion 180B may electrically connect the second contact point 161 and the pad PAD of the uppermost chip 120M to the second circuit layer 141. In some example embodiments, the first portion 180A and the second portion 180B are spaced apart in a horizontal direction. Accordingly, the solder ball 190 may include a first solder ball 190A connected to the first portion 180A of the redistribution layer 180 and a second solder ball 190B connected to the second portion 180B of the redistribution layer 180. The first solder ball 190A and the second solder ball 190B may receive or output different signals, wherein the different signals may be input to the first chip 121 and the second chip 122, respectively, or output from the first chip 121 and the second chip 122, respectively.

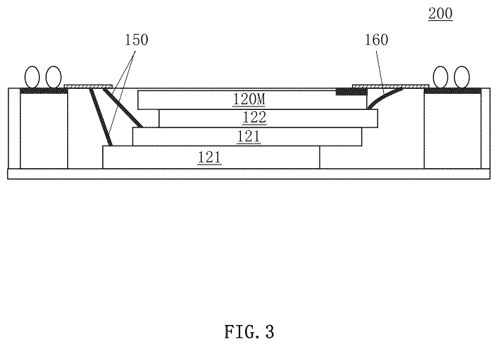

FIG. 3 illustrates a semiconductor package structure according to some example embodiments of the inventive concepts. Elements identical to those illustrated in FIG. 2 will be omitted, and the description will focus on differences between the example embodiments.

As illustrated in FIG. 3, in some example embodiments, the plurality of chips 120 may include a plurality of first chips 121 and a plurality of second chips 122. The plurality of first chips 121 may be disposed between the support substrate 110 and the plurality of second chips 122. In other words, the plurality of first chips 121 may be sequentially stacked on the support substrate 110 and the plurality of second chips 122 may be sequentially stacked on the uppermost first chip.

In some example embodiments, each of the plurality of first chips 121 and the plurality of second chips 122 may shift along the horizontal direction to expose each first pad and each second pad. For example, the plurality of first chips 121 may shift along a first horizontal direction, and the plurality of second chips 122 may shift along a second horizontal direction opposite to the first horizontal direction, such that the chip stack body STK does not easily collapse. That is to say, some of the plurality of first chips 121 and the plurality of second chips 122 may vertically offset in a horizontal direction from each other such that upper surfaces of the plurality of first chips 121 and the plurality of second chips 122 are exposed. The first bonding wire 150 may be connected to the exposed first pad of the first chip 121. The second bonding wire 160 may be connected to the exposed second pad of the second chip 122. In this case, a shortest length of the first bonding wire 150 may be larger than a longest length of the second bonding wire 160, but the example embodiments of the inventive concepts are not limited thereto.

In some example embodiments, the adhesive layer AL may be not disposed between the plurality of chips 120, such that a thickness of the semiconductor package structure 200 may be further reduced. That is to say, bottom surfaces of the plurality of chips 120 may contact, for example directly contact, top surfaces of the plurality of chips 120. In addition, since the first pad of the first chip 121 and the second pad of the second chip 122 are exposed rather than being buried in the adhesive layer AL, the connection reliability of the first bonding wire 150 and the second bonding wire 160 may be improved.

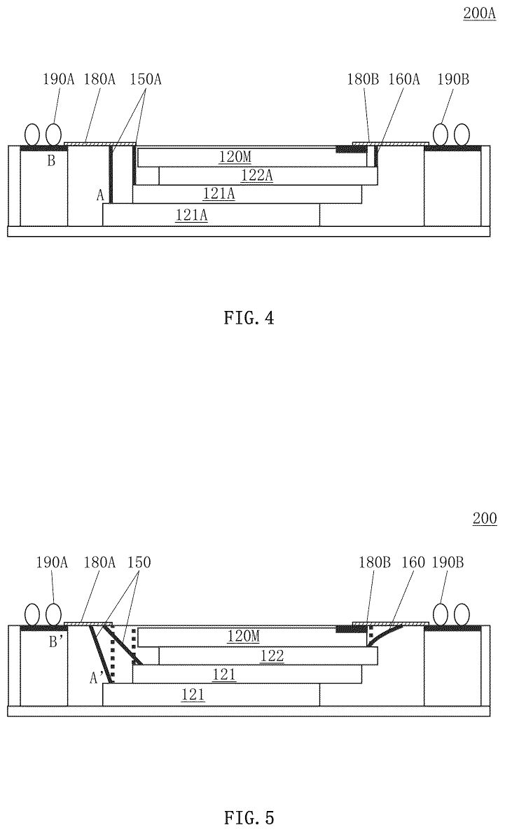

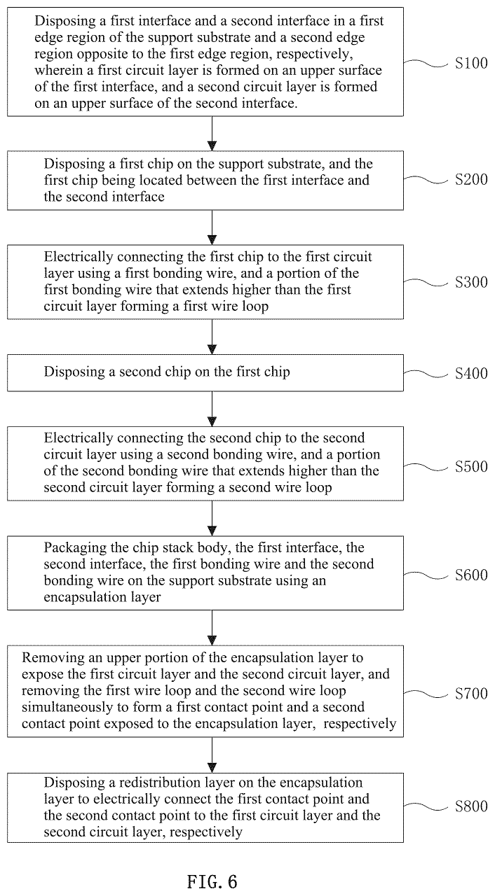

Hereinafter, the semiconductor package structure shown in FIG. 3 will be taken as an example to describe a benefit effect on reducing a length of the interconnect path according to the present inventive conception. FIG. 4 illustrates a semiconductor package structure shown in FIG. 3 according to a comparative example. FIG. 5 illustrates the semiconductor package structure according to the embodiment shown in FIG. 3.

As shown in FIG. 4, in the comparative example, the semiconductor package structure 200A may be the same as the semiconductor package structure 200 of FIG. 3, except for first and second bonding wires 150A and 160A. In the comparative example, first chips 121A included in the semiconductor package structure 200A are connected to the first portion 180A of the redistribution layer 180 via the first bonding wires 150A by a vertical wire bonding process. Second chips 122A included in the semiconductor package structure 200A are connected to the second portion 180B of the redistribution layer 180 via the second bonding wires 160A by the vertical wire bonding process. Taking a lowermost first chip 121A as an example, the lowermost first chip 121A is connected to a first solder ball 190A of the external terminal 190 via an interconnect path AB. The first bonding wire 150A is connected to the first chip 121A at a point A. The first solder ball 190A is connected to the first portion 180A of the redistribution layer 180 at a point B. The interconnect path AB has a first distance from the point A to the point B.

As shown in FIG. 5, in the present embodiment, the first chips 121 included in the semiconductor package structure 200 are connected to the first portion 180A of the redistribution layer 180 via the first bonding wires 150 by a loop wire bonding process. The second chips 122 included in the semiconductor package structure 200 are connected to the second portion 180B of the redistribution layer 180 via the second bonding wires 160 by the loop wire bonding process. Taking a lowermost first chip 121 as an example, the lowermost first chip 121 is connected to a first solder ball 190A of the external terminal 190 via an interconnect path A′B′. The first bonding wire 150 is connected to the first chip 121 at a point A′. The first solder ball 190A is connected to the first portion 180A of the redistribution layer 180 at a point B′. The interconnect path A′B′ has a second distance from the point A′ to the point B′.

It can be seen that the second distance is shorter than the first distance. Thus, the semiconductor package structure formed through the loop wire bonding process can shorten the interconnect paths between semiconductor chips and external terminals so as to speed up signal transmission speed.

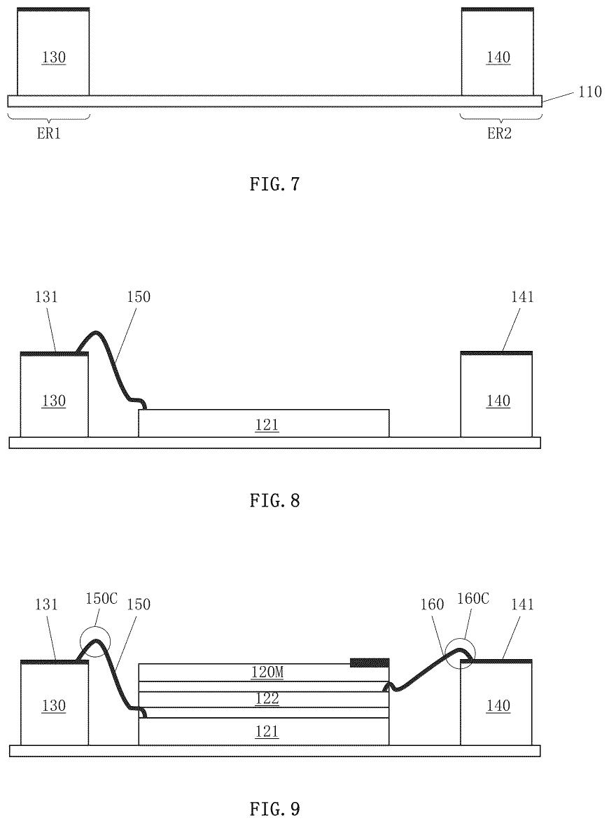

Below, the manufacturing method of the semiconductor package structure according to some example embodiments of the inventive concepts will be described by referring to FIGS. 6-12. However, manufacturing methods of other example embodiments according to the inventive concepts will become clear and apparent according to the following descriptions.

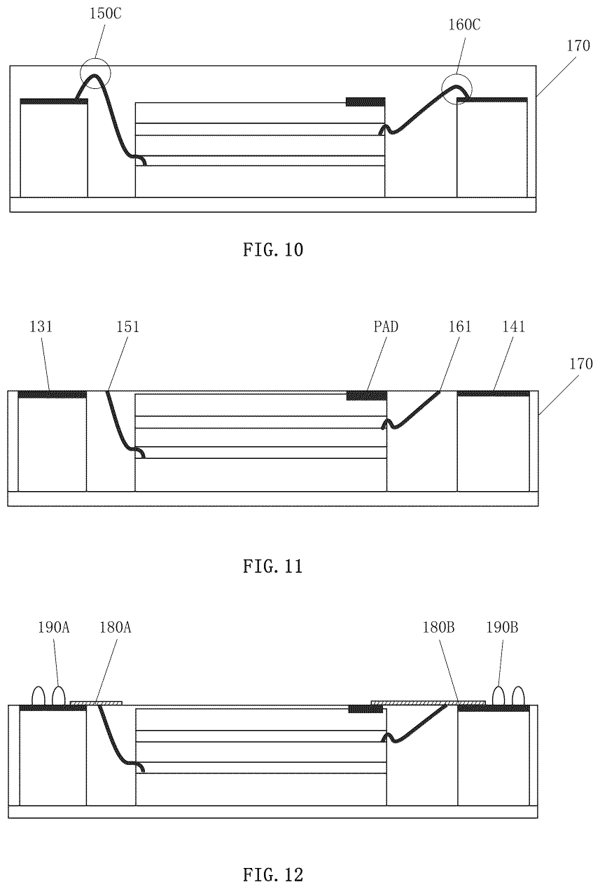

FIG. 6 illustrates a process flowchart of a manufacturing method of the semiconductor package structure according to some example embodiments of the inventive concepts. FIGS. 7-12 illustrate each step of the manufacturing method of the semiconductor package structures according to some example embodiments of the inventive concepts.

Referring to FIGS. 6 and 7 together with FIG. 2, the method of manufacturing the semiconductor package structure 100 includes the following steps. Step S100, the first interface 130 and the second interface 140 are disposed in the first edge region ER1 of the support substrate 110 and the second edge region ER2 opposite to the first edge region ER1, respectively. The first circuit layer 131 is formed on the upper surface of the first interface 130. The second circuit layer 141 is formed on the upper surface of the second interface 140.

Referring to FIG. 8, step S200, the first chip 121 is disposed on the support substrate 110. The first chip 121 is located between the first interface 130 and the second interface 140. In the present example embodiment, the first chip 121 may be the lowermost chip of the plurality of chips 120 included in the semiconductor package structure 100 illustrated in FIG. 2. The first chip 121 may be a memory chip or a controller chip.

Step S300, the first chip 121 is electrically connected to the first circuit layer 131 using the first bonding wire 150, wherein a portion of the first bonding wire 150 that extends higher than the first circuit layer 131 forms a first wire loop 150C. In some example embodiments, the first interface 130 may have a level higher than that of the first chip 121, such that the first bonding wire 150 extends upward a certain distance from the first pad disposed on the upper surface of the first chip 121, and then is bent and changed to extend downward to be connected to the first circuit layer 131 located on the upper surface of the first interface 130, thereby forming the first wire loop 150C.

Next, referring to FIG. 9, step S400, the second chip 122 is disposed on the first chip 121. In some example embodiments, a size and function of the second chip 122 may be different from those of the first chip 121, but the example embodiments of the inventive concepts are not limited thereto. In other example embodiments, the second chip 122 may be the same as the first chip 121.

Step S500, the second chip 122 is electrically connected to the second circuit layer 141 using the second bonding wire 160, wherein a portion of the second bonding wire 160 that extends higher than the second circuit layer 141 forms a second wire loop 160C. In some example embodiments, the second interface 140 may have a level higher than that of the second chip 122, such that the second bonding wire 160 extends upward a certain distance from the second pad disposed on the upper surface of the second chip 122, and then is bent and changed to extend downward to be connected to the second circuit layer 141 located on the upper surface of the second interface 140, thereby forming the second wire loop 160C.

Referring to FIG. 10, step S600, the chip stack body STK, the first interface 130, the second interface 140, the first bonding wire 150 and the second bonding wire 160 are packaged on the support substrate 110 using the encapsulation layer 170. In some example embodiments, a material of the encapsulation layer 170 may be a resin such as EMC. The encapsulation layer 170 may completely cover the first wire loop 150C and the second wire loop 160C, such that the first bonding wire 150 and the second bonding wire 160 are fixed to prevent or reduce in likelihood the wires from being deformed.

Referring to FIG. 11, step S700, an upper portion of the encapsulation layer 170 is removed to expose the first circuit layer 131 and the second circuit layer 141, and the first wire loop 150C and the second wire loop 160C are removed simultaneously to form the first contact point 151 and the second contact point 161 that are exposed to the encapsulation layer 170, respectively. In some example embodiments, the planarization process such as a chemical-mechanical polishing (CMP) process may be performed on the structure obtained in step S600, until the upper surfaces of the first circuit layer 131 and the second circuit layer 141 as well as the upper surface of the pad PAD of the uppermost chip 120M are exposed. In the above planarization process, the first wire loop 150C of the first bonding wire 150 and the second wire loop 160C of the second bonding wire 160 are removed together when the upper portion of the encapsulation layer 170 is removed, thereby exposing the first contact point 151 and the second contact point 161. For example, the first bonding wire 150 and the second bonding wire 160 may extend at oblique angles with respect to the upper surfaces of the first chip 121 and the second chip 122.

Referring to FIG. 12, step S800, the redistribution layer 180 is disposed on the encapsulation layer 170 to electrically connect the first contact point 151 and the second contact point 161 to the first circuit layer 131 and the second circuit layer 141, respectively. In some example embodiments, the redistribution layer 180 may include a plurality of layers of wirings and via holes. The first contact point 151 of the first bonding wire 150 and the second contact point 161 of the second bonding wire 160 may be electrically connected to external elements via the redistribution layer 180.

As the integration of the semiconductor package structure increases, a distance between the elements included in the semiconductor package structure may decrease, and a distance between the wire loops of the plurality of bonding wires may also decrease, resulting in the occurrence of a wire sweeping phenomenon, and thereby reducing the yield of the package. The method of manufacturing the semiconductor package structure according to some example embodiments of the inventive concepts may arrange the bonding wires of the plurality of chips using the first interface and the second interface, which may increase the fan-out area, and may also shorten the interconnect path. In addition, the alignment precision of rewiring may further be improved in the back-end-of-line (BEOL).

Referring to FIG. 12, in some example embodiments, the methods of manufacturing the semiconductor package structure 100 may further include disposing the external terminal 190 on the first circuit layer 131 and the second circuit layer 141. The external terminal 190 is spaced apart from the redistribution layer 180 along the horizontal direction.

Returning to refer to FIG. 2, in some example embodiments, each of the first chip 121 and the second chip 122 may include an active surface and an inactive surface. The active surface may face the redistribution layer 180, and the inactive surface may face the support substrate 110. In addition, in some example embodiments, the first pad on the active surface of the first chip 121 may be adjacent to the first interface 130 and connected to the first bonding wire 150. The second pad on the active surface of the second chip 122 may be adjacent to the second interface 140 and connected to the second bonding wire 160.

Returning to refer to FIGS. 8 and 9, in some example embodiments, the disposing the first chip 121 and electrically connecting it to the first circuit layer 131 and the disposing the second chip 122 and electrically connecting it to the second circuit layer 141 may be repeatedly performed, such that a plurality of first chips 121 and a plurality of second chips 122 are alternately stacked on the support substrate 110 and aligned along the horizontal direction. The adjacent first chip 121 and second chip 122 may be connected to each other via the adhesive layer AL located between them.

Returning to refer to FIG. 3, in the method of manufacturing the semiconductor package structure 200 according to some example embodiments of the inventive concepts, a first number of disposing the first chip 121 and electrically connecting it to the first circuit layer 131 may be firstly performed, and a second number of disposing the second chip 122 and electrically connecting it to the second circuit layer 141 is then performed, such that a number of the plurality of first chips 121 corresponding to the first number are stacked on the support substrate 110, and a number of the plurality of second chips 122 corresponding to the second number are stacked on the uppermost first chip of the plurality of first chips 121. In other words, the plurality of first chips 121 may be disposed between the support substrate 110 and the plurality of second chips 122, and each of the first chips 121 and the second chips 122 shifts (e.g., are vertically offset) along the horizontal direction, to expose the first pad and the second pad.

Returning to refer to FIGS. 9 and 10, before using the encapsulation layer 170, the method of manufacturing the semiconductor package structure 100 may further include: forming a chip stack body STK. The chip stack body STK may include a first chip 121, a second chip 122 and an uppermost chip 120M. As illustrated in FIG. 2, the uppermost chip 120M may be connected to the redistribution layer 180 via the pad PAD disposed on the active surface thereof.

Returning to refer to FIG. 11, after undergoing the planarization process, the encapsulation layer 170 may cover the active surface of the uppermost chip 120M and expose the pad PAD of the uppermost chip 120M.

In some example embodiments, due to the planarization process, the upper surface of the pad PAD of the uppermost chip 120M, the upper surface of the first circuit layer 131, the upper surface of the second circuit layer 141 and the upper surface of the encapsulation layer 170 may be located at the same level.

Returning to refer to FIG. 12, in the disposing the redistribution layer 180, the redistribution layer 180 may include a first portion 180A and a second portion 180B. The first portion 180A of the redistribution layer 180 may electrically connect the first contact point 151 of the first bonding wire 150 to the first circuit layer 131, and the second portion 180B of the redistribution layer 180 may electrically connect the second contact point 161 of the second bonding wire 160 and the pad PAD of the uppermost chip 120M to the second circuit layer 141.

According to some example embodiments of the inventive concepts, the wire sweeping problem caused when realizing the fan-out package structure based on the wire bonding technology may be improved by disposing the first interface and the second interface with the interconnect layer formed by the first circuit layer, the second circuit layer and the redistribution layer. Meanwhile, the bonding wires of the plurality of chips are arranged using the first interface and the second interface, which may increase the fan-out area, shorten the interconnect path, and may further improve the alignment precision of rewiring in the back-end-of-line (BEOL).

Although the example embodiments of the present inventive concepts have been shown and described, it will be understood by those skilled in the art that various modifications and changes may be made therein without departing from the spirit and scope of the inventive concept as defined by the following claims.

What is claimed is:

1. A semiconductor package structure, comprising:
a support substrate;
a chip stack body, including a plurality of chips stacked on the support substrate;
a first interface, in a first edge region of the support substrate, and a first circuit layer on an upper surface of the first interface;
a second interface, in a second edge region opposite to the first edge region of the support substrate, a second circuit layer on an upper surface of the second interface, and the chip stack body between the first interface and the second interface;
a first bonding wire, connected to a first chip of the plurality of chips and having a first contact point at an end thereof;
a second bonding wire, connected to a second chip of the plurality of chips and having a second contact point at an end thereof;
an encapsulation layer, surrounding the chip stack body, the first interface, the second interface, the first bonding wire and the second bonding wire on the support substrate, and exposing the first contact point, the second contact point, the first circuit layer and the second circuit layer; and
a redistribution layer, on the encapsulation layer and electrically connecting the first contact point and the second contact point to the first circuit layer and the second circuit layer, respectively.

2. The semiconductor package structure of claim 1, wherein each of the plurality of chips includes an active surface and an inactive surface, the active surface faces the redistribution layer, and the inactive surface faces the support substrate.

3. The semiconductor package structure of claim 2, wherein a first pad on the active surface of the first chip is between the first interface and the chip stack body and connected to the first bonding wire, and
a second pad on the active surface of the second chip is between the second interface and the chip stack body and connected to the second bonding wire.

4. The semiconductor package structure of claim 3, wherein the first chip and the second chip are alternately stacked on the support substrate and aligned along a horizontal direction.

5. The semiconductor package structure of claim 2, wherein an uppermost chip of the plurality of chips is connected to the redistribution layer via a pad on the active surface.

6. The semiconductor package structure of claim 5, wherein the encapsulation layer covers the active surface of the uppermost chip and exposes the pad of the uppermost chip.

7. The semiconductor package structure of claim 6, wherein an upper surface of the pad of the uppermost chip, an upper surface of the first circuit layer, an upper surface of the second circuit layer and an upper surface of the encapsulation layer are located at a same level.

8. The semiconductor package structure of claim 5, wherein
the redistribution layer includes a first portion and a second portion,
the first portion electrically connects the first contact point to the first circuit layer, and
the second portion electrically connects the second contact point and the pad of the uppermost chip to the second circuit layer.

9. The semiconductor package structure of claim 1, further comprising:
an external terminal on the first circuit layer and the second circuit layer and spaced apart from the redistribution layer along a horizontal direction.

10. A semiconductor package structure, comprising:
a support substrate;
a chip stack body, including a plurality of chips stacked on the support substrate;
a first interface, in a first edge region of the support substrate, and a first circuit layer on an upper surface of the first interface;
a second interface, in a second edge region opposite to the first edge region of the support substrate, a second circuit layer on an upper surface of the second interface, and the chip stack body between the first interface and the second interface;
a first bonding wire, connected to a first chip of the plurality of chips and having a first contact point at an end thereof;
a second bonding wire, connected to a second chip of the plurality of chips and having a second contact point at an end thereof, and the first chip is between the support substrate and the second chip, and each of the first chip and the second chip are vertically offset in a horizontal direction;
an encapsulation layer, surrounding the chip stack body, the first interface, the second interface, the first bonding wire and the second bonding wire on the support substrate, and exposing the first contact point, the second contact point, the first circuit layer and the second circuit layer; and
a redistribution layer, on the encapsulation layer and electrically connecting the first contact point and the second contact point to the first circuit layer and the second circuit layer, respectively.

11. A method of manufacturing a semiconductor package structure, comprising:
disposing a first interface and a second interface in a first edge region of a support substrate and a second edge region opposite to the first edge region, respectively, wherein a first circuit layer is formed on an upper surface of the first interface, and a second circuit layer is formed on an upper surface of the second interface;
disposing a first chip on the support substrate, the first chip being located between the first interface and the second interface;
electrically connecting the first chip to the first circuit layer using a first bonding wire, a portion of the first bonding wire that extends higher than the first circuit layer forming a first wire loop;
disposing a second chip on the first chip to form a chip stack body;
electrically connecting the second chip to the second circuit layer using a second bonding wire, a portion of the second bonding wire that extends higher than the second circuit layer forming a second wire loop;
packaging the chip stack body, the first interface, the second interface, the first bonding wire and the second bonding wire on the support substrate using an encapsulation layer;
removing an upper portion of the encapsulation layer to expose the first circuit layer and the second circuit layer, and removing the first wire loop and the second wire loop simultaneously to form a first contact point and a second contact point exposed to the encapsulation layer, respectively; and
disposing a redistribution layer on the encapsulation layer to electrically connect the first contact point and the second contact point to the first circuit layer and the second circuit layer, respectively.

12. The method of claim 11, wherein
each of the first chip and the second chip includes an active surface and an inactive surface,
the active surface faces the redistribution layer, and
the inactive surface faces the support substrate.

13. The method of claim 12, wherein
a first pad on the active surface of the first chip is adjacent to the first interface and connected to the first bonding wire, and
a second pad on the active surface of the second chip is adjacent to the second interface and connected to the second bonding wire.

14. The method of claim 13, wherein the disposing the first chip and electrically connecting it to the first circuit layer and the disposing the second chip and electrically connecting it to the second circuit layer are repeatedly performed, such that a plurality of first chips and a plurality of second chips are alternately stacked on the support substrate and aligned along a horizontal direction.

15. The method of claim 13, wherein
the disposing the first chip includes disposing a plurality of first chips and electrically connecting the plurality of first chips to the first circuit layer, and
the disposing the second chip includes disposing a plurality of second chips and electrically connecting the plurality of second chips to the second circuit layer, such that the plurality of the first chips are disposed between the support substrate and the plurality of the second chips, and each of the plurality of first chips and the plurality of second chips are vertically offset in a horizontal direction.

16. The method of claim 12, wherein before using the encapsulation layer, the method further comprises:
forming the chip stack body, the chip stack body including the first chips, the second chips and an uppermost chip, and the uppermost chip being connected to the redistribution layer via a pad disposed on the active surface.

17. The method of claim 16, wherein the encapsulation layer covers the active surface of the uppermost chip and exposes the pad of the uppermost chip.

18. The method of claim 17, wherein an upper surface of the pad of the uppermost chip, an upper surface of the first circuit layer, an upper surface of the second circuit layer and an upper surface of the encapsulation layer are located at a same level.

19. The method of claim 16, wherein
the redistribution layer comprises a first portion and a second portion,
the first portion electrically connects the first contact point to the first circuit layer, and
the second portion electrically connects the second contact point and the pad of the uppermost chip to the second circuit layer.

20. The method of claim 11, further comprising:
disposing an external terminal on the first circuit layer and the second circuit layer, the external terminal being spaced apart from the redistribution layer along a horizontal direction.
